(19) United States
(12) Patent Application Publication
(10) Pub. No.: US 2008/0158840 A1
(43) Pub. Date: Jul. 3, 2008

(54) DC power plane structure

(75) Inventors: Yen-Hao Chen, Taipei (TW); Chun-Yu Lai, Taipei (TW)

Correspondence Address: RABIN & Berdo, PC, 1101 14TH STREET, NW, SUITE 500, WASHINGTON, DC, 20005, US

(73) Assignee: INVENTEC CORPORATION, Taipei (TW)

(21) Appl. No.: 11/645,502

(22) Filed: Dec. 27, 2006

(51) Int. Cl. H05K 1/16; H05K 1/00

(52) U.S. Cl. 361/782; 361/748; 361/794

(57) ABSTRACT

A DC power plane structure applied in multi-layer circuit board is provided. The DC power plane structure includes a first circuit area for receiving a DC power, a noise filter with one end electrically connected to a DC power output end of the first circuit area, and a second circuit area which is electrically isolated from the first circuit area. The second circuit area has a band gap structure, and the DC power input end of the band gap structure is electrically connected to the other end of the noise filter for inhibiting high-frequency noise generated between layers of the multi-layer circuit board.

### BACKGROUND OF THE INVENTION

1. Field of Invention

The present invention relates to a direct current (DC) power plane structure, and more particularly to a DC power plane structure for inhibiting noise between layers of a multi-layer circuit board.

2. Related Art

Recently, as the mass are increasingly demanding for higher information transmission speed, the frequency of signal transmission becomes higher and higher. Thus, a high-frequency digital circuit design becomes a main development field of circuit design towards higher speed, compacted volume, and low voltage. Due to the demand for a design with small volume, multi-layer printed circuit boards have been widely applied in the circuit design. However, as the signal transmission frequency becomes higher, noise is generated between a power plane and a ground plane in the multi-layer printed circuit board, which negatively affects the signal transmission quality. Accordingly, how to inhibit noise transmitted along with signals has become an important subject in high-frequency digital circuit design.

In a high-frequency digital circuit, when a signal line is connected to a power plane, parasitic inductance, capacitance, and resistance effects occurs between the layers of the multi-layer printed circuit board. When quickly switching signals of an integrated circuit (IC) in the high-frequency digital circuit, a transient voltage difference is generated in the power plane, thus causing noise. The noises are further propagated to other positions in the circuit in the form of parallel plate waveguide, which are one of the major noise sources in digital system.

However, some common methods of inhibiting wideband noises have been disclosed in prior arts, in which capacitance walls, capacitors with a high capacitance are arranged and power planes are partitioned to inhibit the noise. In the design of arranging capacitors, decoupling capacitors are arranged around a noise source to provide a noise ground path. Generally, the more the capacitors are arranged around the noise source, the better the effect of noise inhibition is. However, in the above designs, resonance noises of certain frequencies still exist, which cause inconvenience in the layout of wirings on the circuit board. Thus, the manufacturing cost is greatly increased, and the concept of short, small, light, and thin design cannot be achieved.

Also, referring to FIGS. 1 and 2, an exploded structural view of a multi-layer circuit board and a top view of a power plane in the prior art are shown. As shown in FIGS. 1 and 2, the method of inhibiting the wideband noise by partitioning a power plane 10 is provided, in which the power plane 10 is partitioned into a first circuit area 11 and a second circuit area 12 with a slit there between. The first circuit area 11 has an component or IC that is tendered to be interfered by the noise to generate a resonance, and the second circuit area has an input/output port (I/O port) 14. Thus, the slit has a function of isolating the noise. The two areas are electrically connected with each other only by a noise filter 13 to let signals pass through and filter a part of noise. The noise filter 13 is a ferrite bead which is a ferromagnetic material. The ferrite bead can increasingly generate higher impedance as the frequency goes up, and a ferrite material may react with a magnetic field resulting from the circuit, resulting in a loss. Different ferrite materials and geometrical structures may cause an attenuation effect to different frequencies.

The method described above can overcome the problem of high cost due to employing the capacitance wall. However, the partitioned power plane 10 may result in a high-frequency resonance between the power plane 10 and a ground plane 20. The noise filter 13 can only filter noise with low frequency and cannot reduce the high-frequency noise, and thus high-frequency noise is transmitted with signals via the transmission line. This is a difficult problem in the prior art.

Nowadays, high-frequency signal transmission becomes a main trend for signal transmission, and the high-frequency noise will interfere with high-frequency signals, resulting in a distortion of the high-frequency signals. Therefore, it is an important subject for the design of high-frequency digital circuit to effectively inhibit the high-frequency noise transmitted on the power plane 10.

### SUMMARY OF THE INVENTION

In view of the above problems, it is a main object of the present invention to provide a power plane structure for inhibiting high-frequency noise, so as to solve the problems existing in the prior art that the method of partitioning the power plane can only inhibit low-frequency noise other than the high-frequency noise as the resonance of high-frequency noise is caused. And the high manufacturing cost caused by the use of a large number of capacitors in the conventional art can be reduced, also solving the problem of difficult wiring layout and complicated manufacturing processes.

In order to achieve the above object, the present invention provides a DC power plane structure arranged in a multi-layer circuit board. The DC power plane structure includes a first circuit area for inputting a DC power, a noise filter with one end electrically connected to a DC power output end of the first circuit area, and a second circuit area which is electrically isolated from the first circuit area. The second circuit area is formed with a band gap structure, and the DC power input end of the band gap structure is electrically connected to the other end of the noise filter. According to the present invention, the band gap structure can also be formed in the first circuit area, and one end of the noise filter is electrically connected to the DC power output end of the band gap structure, and the DC power input end of the second circuit area is electrically connected to the other end of the noise filter.

The efficacy of the present invention is to provide a DC power plane structure, which adopts the technique of partitioning the power plane and meanwhile forming an electromagnetic band gap (EBG) or photonic band gap (PBG) structure on the power plane, so that both the low-frequency and high-frequency noise can be inhibited at the same time, thereby greatly improving the signal transmission quality. Also, the above design does not need to use a large number of capacitors or arrange capacitors with a high capacitance, thus reducing the manufacturing cost, simplifying the manufacturing processes of the circuit board structure, and achieving the short, small, light, and thin design.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and thus are not limitative of the present invention, and wherein:

FIG. 1 is an exploded structural view of a multi-layer circuit board in the prior art;

FIG. 2 is a top view of a power plane in the prior art;

FIG. 3 is a top view of the first embodiment of the present invention;

FIG. 4 is a top view of the second embodiment of the present invention;

FIG. 5 is a top view of the third embodiment of the present invention; and

FIG. 6 shows the relationship between frequencies and noise signal intensity.

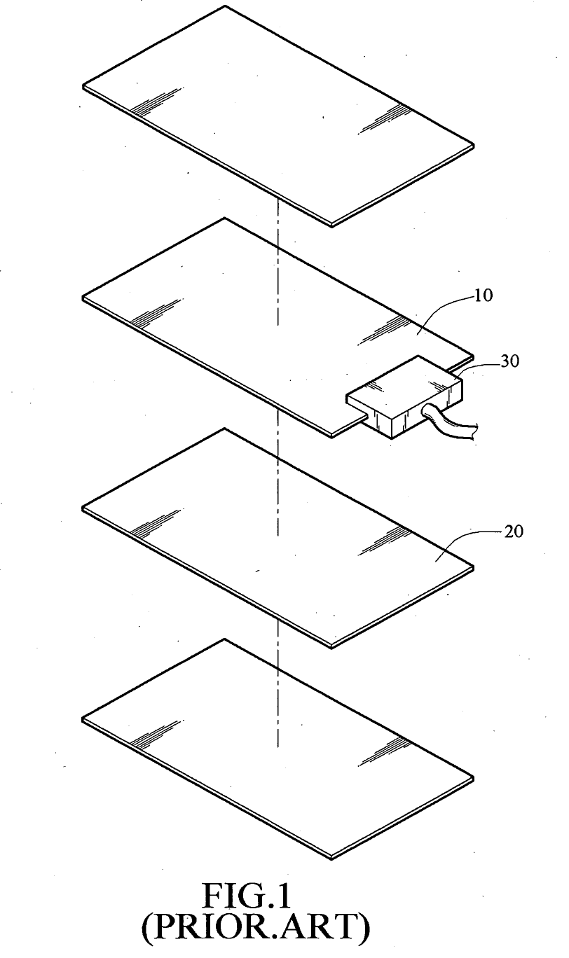

### DETAILED DESCRIPTION OF THE INVENTION

The purpose, construction, characteristics, and functions of the present invention are further described accompanied with the embodiments below.

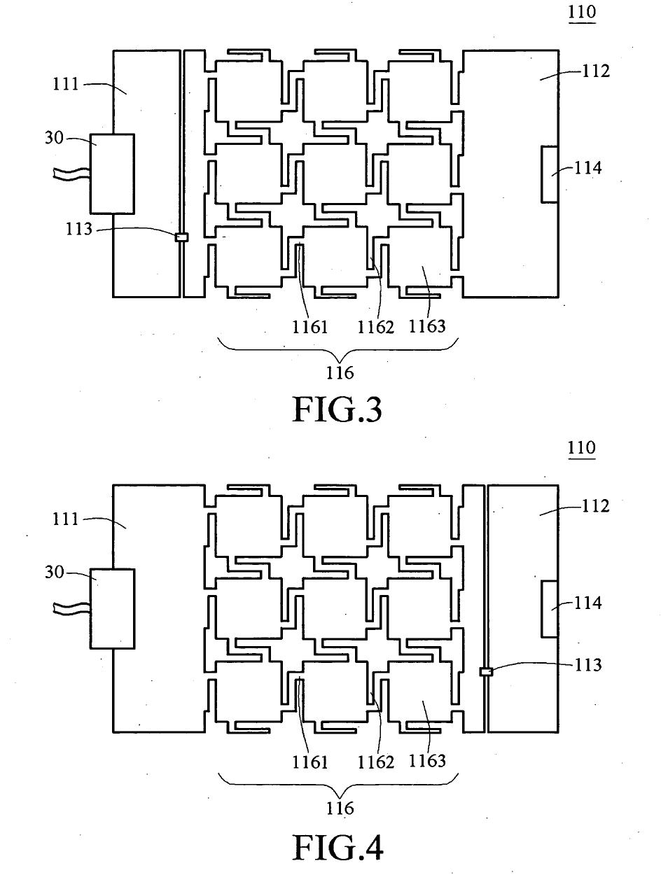

First, referring to FIG. 3, a top view of the first embodiment of the present invention is shown. As shown in FIG. 3, a power plane 110 has a DC power 30, and an I/O port 114 for connecting a transmission line so that the power plane 110 is connected with another circuit board to transmit or receive a signal. The power plane 110 is partitioned into two parts, namely a first circuit area 111 and a second circuit area 112 which are electrically connected through a noise filter 113, and a band gap structure 116 is formed on the second circuit area 112.

A band gap structure 116, for example, an electromagnetic band gap (EBG) structure or a photonic band gap (PBG) structure is formed on the second circuit area 112, so as to make one end of the noise filter 113 electrically connected to the DC power output end of the first circuit area 111. Also, the second circuit area 112 is electrically isolated from the first circuit area 111, and the DC power input end of the band gap structure 116 is electrically connected to the other end of the noise filter 113, so as to inhibit the transmission of low-frequency noise, thereby achieving the filtering effect. The main function of the band gap structure 116 in the present invention is to inhibit the high-frequency noise propagating on the power plane 110. As shown in FIG. 3, the band gap structure 116 has, for example, thin-wire channel structures 1161, thin slit structures 1162, and units 1163, and each of them has a function of inhibiting noise. The thin-wire channel structures 1161 mainly function to provide an equivalent inductance. The thin-wire channel structures 1161 refer to connecting structures between any two units 1163 or connecting structures between one of the units 1163 and the second circuit area 112. The thin slit structure 1162 mainly functions to provide an equivalent inductance. The thin slit structures 1162 refer to slits between the units 1163 and the thin-wire channel structures 1161 and slits between the units 1163 and the second circuit area 112. Thus, the above band gap structure 116 is an equivalent circuit connected in parallel with a plurality of capacitors and inductors, through which a great number of noise ground paths can be provided to achieve the purpose of filtering and inhibiting high-frequency. noise, thereby solving the problems existing in the prior art.

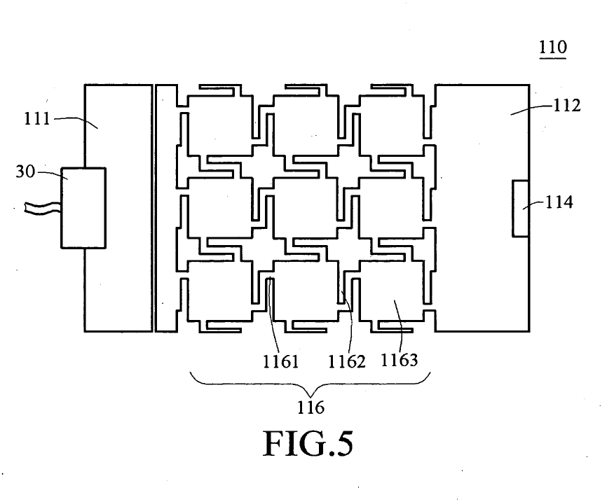

Furthermore, referring to FIG. 4, a top view of the second embodiment of the present invention is provided. As shown in FIG. 4, the second embodiment of the present invention is substantially the same as the first embodiment in terms of main structures, and only the difference is described herein. The band gap structure 116 is formed on the first circuit area 111 in the second embodiment so that one end of the noise filter 113 is electrically connected to the DC power output end of the band gap structure 116, the second circuit area 112 is electrically isolated from the first circuit area 111, and the DC power input end of the second circuit area 112 is electrically connected to the other end of the noise filter 113. The filtering effect of the second embodiment is the same as that described in the first embodiment, thereby achieving the function of inhibiting the high-frequency noise. The embodiments of the present invention are not limited to the first and second embodiments. According to the present invention, the band gap structure 116 can also be formed both on the second circuit area 112 and on the first circuit area 111, and other parts are the same as those described in the first and second embodiments, and thus the effect of inhibiting noise can be further improved.

Besides, referring to FIG. 5, a top view of the third embodiment of the present invention is provided. As shown in FIG. 5, the third embodiment of the present invention is similar to the first embodiment in terms of main structures, and only the difference is that there is no noise filter between the first circuit area 111 and the second area 112. Therefore, in the third embodiment, one more limitation is that the first circuit area 111 and the second area 112 should respectively possess different electric potential. Then the filtering effect of the third embodiment with the band gap structure 116 on the first circuit area 111 or the second area 112 is also effective as that described in the first or the second embodiment, thereby achieving the function of inhibiting the high-frequency noise.

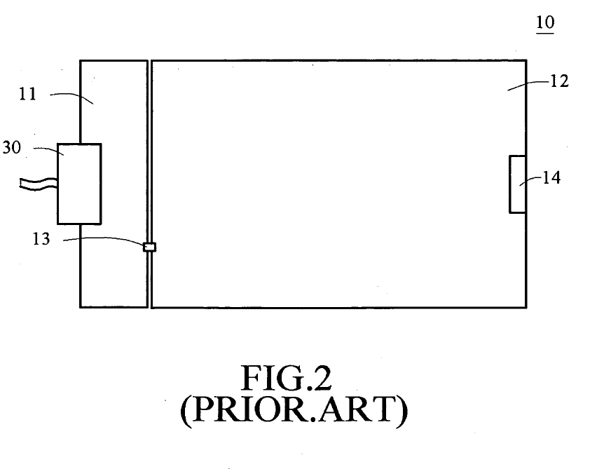

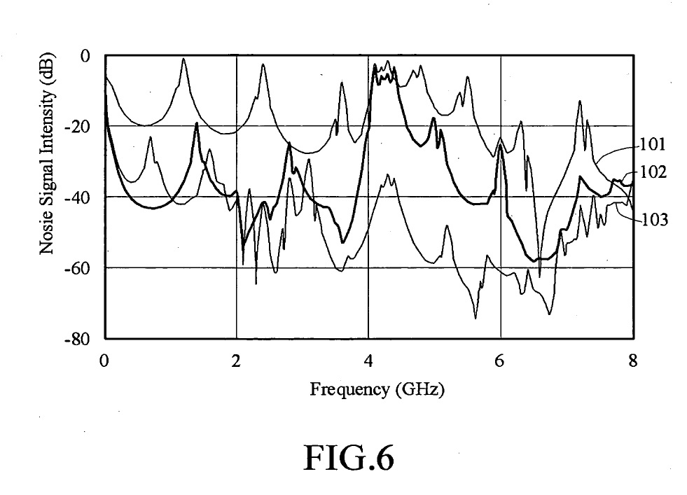

The relationship between frequencies and noise signal intensity is shown in FIG. 6, in order to illustrate the effect of solving the problem of the interference caused by wideband noise between layers of a multi-layer circuit board, which effectively inhibits the transmission of noise. As shown in FIG. 6, a distribution curve 101 denotes the relationship between frequencies and noise signal intensity when the power plane 110 has not partitioned in two parts and the band gap structure 116 is not formed. A distribution curve 102 denotes the relationship between frequencies and noise signal intensity when the power plane 110 is partitioned into the first circuit area 111 and the second circuit area 112 but the band gap structure 116 is not formed, for example, the power plane 10 structure as shown in FIG. 2. A distribution curve 103 denotes the relationship between frequencies and noise signal intensity when the power plane 110 is partitioned into the first circuit area 111 and the second circuit area 112 and the band gap structure 116 is formed on at least one circuit areas, for example, the power plane 110 structure shown in FIG. 3 to 5. The distribution curves 101, 102 and 103 are obtained from the calculation and simulation by using simulation software Zeland IE3D.

Moreover, by comparing the distribution curve 101 with the distribution curve 102, it can be seen that the noise signal intensity with the frequency below 4 GHz in the distribution curve 102 is about 20 dB lower than the noise signal intensity in the distribution curve 101. However, the signal intensity with the frequency above 4 GHz in the distribution curve 102 is only 5 to 10 dB lower than the noise signal intensity in the distribution curve 101. Thus, it can be seen that the partitioned structures of power plane 10 in the prior art as shown in FIG. 2 can significantly inhibit low-frequency noise but cannot effectively inhibit high-frequency noise propagating on the power plane 10.

Comparing the distribution curve 102 with the distribution curve 103, it can be seen that the noise signal intensity with the frequency above 4 GHz in the distribution curve 103 greatly decreases as compared with the noise signal intensity in the distribution curve 102. And the noise signal intensity with the frequency between 4 GHz to 8 GHz is decreased about 22 dB, while the noise signal intensity with the frequency between 4 GHz to 6.5 GHz is even decreased about 28 dB. That is, the distribution curve 103 indicates that the band gap structure 116 formed on the power plane 110 structure in the present invention has a great effect of inhibiting high-frequency noise. However, when comparing the distribution curve 103 with the distribution curve 102 at the frequency below 4 GHz, the noise signal intensity does not decrease significantly. Thus, it can be seen that the band gap structure 116 formed on the power plane 110 structure in the present invention does not have the effect of inhibiting the noise with the frequency below 4 GHz.

Therefore, the present invention provides a DC power plane structure applied in the multi-layer circuit board, in which the technique of partitioning the power plane 110 for effectively inhibiting low-frequency noise with the frequency below 4 GHz and the technique of forming a band gap structure 116 on the first circuit area or the second circuit area for effectively inhibiting the transmission of high-frequency noise, especially those with the frequency between 4 GHz to 8 GHz are used together.

The present invention can solve the problem existing in the prior arts. That is, the technique of partitioning the power plane 10 cannot be used to effectively inhibit high-frequency noise only, so that the high-frequency noise will be easily transmitted to the I/O port and then output via the transmission line, thereby affecting the transmission quality of the high-frequency signal. Therefore, by partitioning the power plane 110 and meanwhile forming the band gap structure 116 on the power plane 110, the present invention can inhibit both low-frequency and high-frequency noise signals so as to greatly improve the signal transmission quality. Furthermore, the above-mentioned design does not need to use a large number of capacitors or arrange capacitors with high capacitance, thus reducing the manufacturing cost, simplifying the manufacturing processes of the circuit board, and achieving a short, small, light and thin design.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A direct current (DC) power plane structure applied in a multi-layer circuit board, comprising:
a first circuit area for receiving a DC power; and
a second circuit area which is electrically isolated from the first circuit area, wherein the second circuit area is formed with a band gap structure.

2. The DC power plane structure of claim 1, the direct current power plane structure further comprises a noise filter with one end being electrically connected to a DC power output end of the first circuit area and the other end of the noise filter is electrically connected to the DC power input end of the band gap structure.

3. The DC power plane structure of claim 1, wherein the second circuit area has an I/O (Input/Output) port used for connecting a transmission line such that the second circuit area is connected to another circuit board to transmit or receive a signal.

4. The DC power plane structure of claim 1, wherein the band gap structure comprises:
a plurality of units;
a plurality of thin-wire channel structures, connected between any two of the units and between the units and the second circuit area, so as to serve as a plurality of inductors for the band gap structure; and
a plurality of thin slit structures, disposed between the units and the thin-wire channel structures and between the units and the second circuit area so as to serve as a plurality of capacitors for the band gap structure, and connected in series with the thin-wire channel structures to form a plurality of noise ground paths.

5. The DC power plane structure of claim 2, wherein the noise filter is a ferrite bead.

6. The DC power plane structure of claim 1, wherein the band gap structure is an electromagnetic band gap (EBG) structure.

7. The DC power plane structure of claim 1, wherein the band gap structure is a photonic band gap (PBG) structure.

8. A direct current (DC) power plane structure applied in a multi-layer circuit board, comprising:
a first circuit area for receiving a DC power, the first circuit area being formed with a band gap structure; and
a second circuit area electrically isolated from the first circuit area.

9. The DC power plane structure of claim 8, the direct current power plane structure further comprises a noise filter with one end being electrically connected to a DC power output end of the band gap structure, and the other end of the noise filter is electrically connected to the DC power input end of the second circuit area.

10. The DC power plane structure of claim 8, wherein the second circuit area has an I/O port for connecting a transmission line such that the second circuit area is connected to another circuit board to transmit or receive a signal.

11. The DC power plane structure of claim 8, wherein the band gap structure comprises:
a plurality of units;
a plurality of thin-wire channel structures, connected between any two of the units and between the units and the first circuit area, so as to serve as a plurality of inductors for the band gap structure; and
a plurality of thin slit structures, disposed between the units and the thin-wire channel structures and between the units and the first circuit area so as to serve as a plurality of capacitors for the band gap structure, and connected in series with the thin-wire channel structures so as to form a plurality of noise ground paths.

12. The DC power plane structure of claim 9, wherein the noise filter is a ferrite bead.

13. The DC power plane structure of claim 8, wherein the band gap structure is an electromagnetic band gap (EBG) structure.

14. The DC power plane structure of claim 8, wherein the band gap structure is a photonic band gap (PBG) structure.
